(19) United States
(12) Patent Application Publication
(10) Pub. No.: US 2025/0107256 A1
(43) Pub. Date: Mar. 27, 2025

(54) PIXEL OF IMAGE SENSOR

(71) Applicant: Samsung Electronics Co., Ltd., Suwon-si (KR)

(72) Inventors: Jihun KIM, Suwon-si (KR); Seungwon Cha, Suwon-si (KR); Seunghan Hong, Suwon-si (KR)

(73) Assignee: Samsung Electronics Co., Ltd., Suwon-si (KR)

(21) Appl. No.: 18/896,249

(22) Filed: Sep. 25, 2024

(30) Foreign Application Priority Data
Sep. 25, 2023 (KR) 10-2023-0128527
Feb. 7, 2024 (KR) 10-2024-0019163

(51) Int. Cl. H01L 27/146

(52) U.S. Cl. CPC H10F 39/8027

(57) ABSTRACT

A pixel including: a first sub-pixel including a plurality of first photodiodes and a first reset transistor; and a second sub-pixel including a plurality of second photodiodes and a second reset transistor, wherein the first sub-pixel shares a floating diffusion node with the second sub-pixel, and wherein a length in a first direction of a metal line for sharing the floating diffusion node is shorter than a length in the first direction of a line connecting a center point of the first sub-pixel to a center point of the second sub-pixel.

### CROSS-REFERENCE TO RELATED APPLICATION

This application is based on and claims priority under 35 U.S.C. § 119 to Korean Patent Application No. 10-2023-0128527, filed on Sep. 25, 2023, and Korean Patent Application No. 10-2024-0019163, filed on Feb. 7, 2024, in the Korean Intellectual Property Office, the disclosures of which are incorporated by reference herein in their entireties.

### BACKGROUND

### 1. Field

The disclosure relates to a pixel of an image sensor. More particularly, to a connection structure of floating diffusion regions of sub-pixels including a plurality of photodiodes.

### 2. Description of Related Art

Image sensors, which may be semiconductor elements for converting an optical signal incident from an outside of the image sensor to an electrical signal, may generate image information corresponding to the incident optical signal. With the development of the computer and communications industries, the demands for image sensors have increased in various fields such as digital cameras, camcorders, mobile phones, surveillance cameras, and medical micro-cameras.

In particular, complementary metal-oxide semiconductor (CMOS) image sensors (CISs) may have a relatively simple driving method and may integrate analog and digital signal processing circuits into a single chip, thereby allowing a size of products to be reduced. In addition, the CISs may have relatively low power consumption and therefore may be widely used as image sensors for mobile devices or other products with limited battery capacity.

### SUMMARY

Provided is a connection structure between sub-pixels, which may ensure high conversion gain.

Also provided is a pixel.

In accordance with an aspect of the disclosure, a pixel includes: a first sub-pixel including a plurality of first photodiodes and a first reset transistor; and a second sub-pixel including a plurality of second photodiodes and a second reset transistor, wherein the first sub-pixel shares a floating diffusion node with the second sub-pixel, and wherein a length in a first direction of a metal line for sharing the floating diffusion node is shorter than a length in the first direction of a line connecting a center point of the first sub-pixel to a center point of the second sub-pixel.

In accordance with an aspect of the disclosure, a pixel includes: a first sub-pixel; and a second sub-pixel, wherein the first sub-pixel comprises: a first plurality of photoelectric conversion regions including a first photoelectric conversion region, a second photoelectric conversion region, a third photoelectric conversion region, and a fourth photoelectric conversion region; and a first floating diffusion region, wherein the first plurality of photoelectric conversion regions and the first floating diffusion region are spaced apart in a direction perpendicular to the first plurality of photoelectric conversion regions, wherein the second sub-pixel comprises: a second plurality of photoelectric conversion regions including a fifth photoelectric conversion region, a sixth photoelectric conversion region, a seventh photoelectric conversion region, and an eighth photoelectric conversion region; and a second floating diffusion region, wherein the second plurality of photoelectric conversion regions and the second floating diffusion region are spaced apart in a direction perpendicular to the second plurality of photoelectric conversion regions, wherein the first floating diffusion region is connected to the second floating diffusion region by a first metal line, wherein the first floating diffusion region is above the first plurality of photoelectric conversion regions, and wherein the second floating diffusion region is above the second plurality of photoelectric conversion regions.

In accordance with an aspect of the disclosure, a pixel having a 2×4 structure, includes: a first sub-pixel; and a second sub-pixel, wherein a structure of the first sub-pixel is symmetrical to a structure of the second sub-pixel with respect to a center point of the pixel, and wherein a length of a first metal line connecting a first floating diffusion region of the first sub-pixel to a second floating diffusion region included in the second sub-pixel is shorter than a length of a line connecting a center point of the first sub-pixel to a center point of the second sub-pixel.

### BRIEF DESCRIPTION OF THE DRAWINGS

The above and other aspects, features, and advantages of certain embodiments of the present disclosure will be more apparent from the following detailed description taken in conjunction with the accompanying drawings in which:

FIG. 1 is a block diagram illustrating an image sensor according to an embodiment;

FIG. 2 is a circuit diagram illustrating a sub-pixel according to an embodiment;

FIG. 3 is a circuit diagram illustrating a pixel according to an embodiment;

FIG. 4 is a plan view of a sub-pixel corresponding to the circuit diagram of FIG. 2, according to an embodiment;

FIG. 5 is a plan view of a pixel corresponding to the circuit diagram of FIG. 3, according to an embodiment;

FIG. 6 is a diagram for explaining a correspondence between the circuit diagram of the pixel of FIG. 3 and the plan view of the pixel of FIG. 5, according to an embodiment.

FIG. 7 is a cross-sectional view of the pixel of FIG. 5, according to an embodiment;

FIG. 8 is a plan view of a pixel according to an embodiment;

FIG. 9 is a plan view of a pixel according to an embodiment;

FIG. 10 is a plan view of a pixel according to an embodiment;

FIG. 11 is a plan view of a pixel according to an embodiment;

FIG. 12 is a plan view of a pixel according to an embodiment; and

FIG. 13 is a plan view of a pixel according to an embodiment.

### DETAILED DESCRIPTION OF THE EMBODIMENTS

Hereinafter, embodiments are described with reference to the accompanying

### DRAWINGS

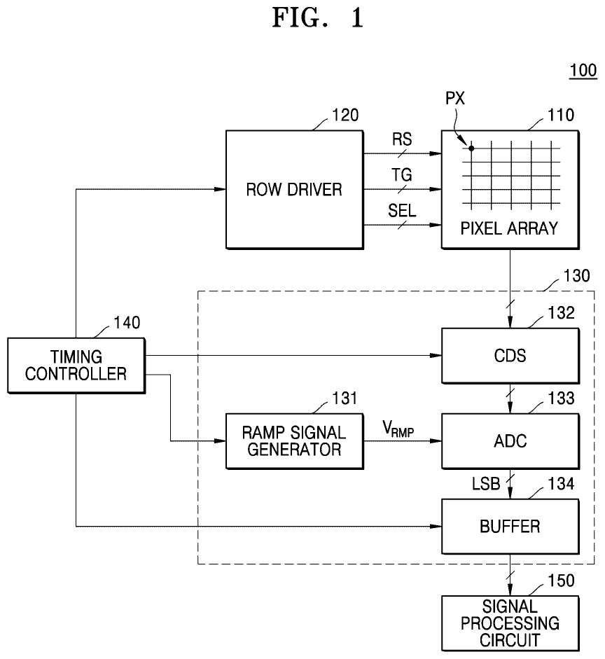

FIG. 1 is a block diagram illustrating an image sensor according to an embodiment.

Referring to FIG. 1, an image sensor 100 according to an embodiment may include a pixel array 110, a row driver 120, a readout circuit 130, a timing controller 140, and a signal processing circuit 150.

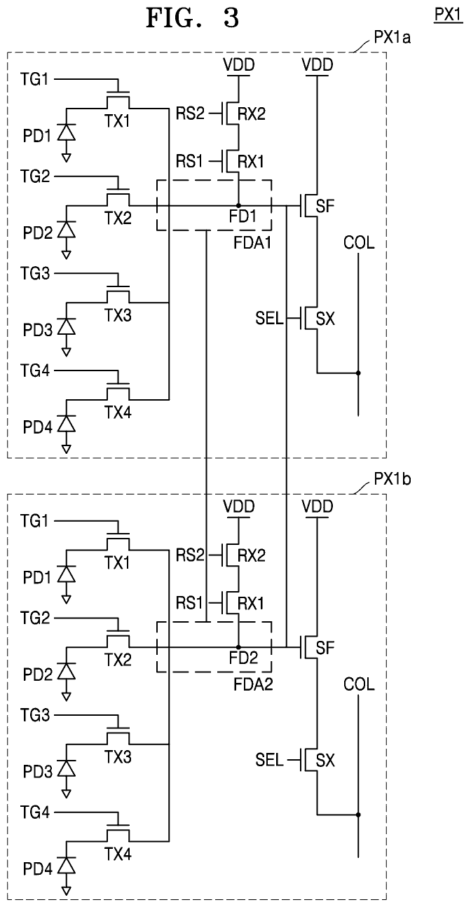

The image sensor 100 may convert light received from outside, for example from an outside of the image sensor 100, into an electrical signal and generate image data. The pixel array 110 included in the image sensor 100 may include a plurality of pixels PX, and the plurality of pixels PX may include a photoelectric device configured to receive light and generate charge, for example, a photodiode. The plurality of pixels PX may be connected to a plurality of row lines extending in a first direction and a plurality of column lines extending in a second direction. In an embodiment, each pixel PX of the plurality of pixels PX may include two or more photodiodes. Two or more photodiodes may be included in the plurality of pixels PX so that each pixel PX may generate pixel signals corresponding to beams of light of various colors, or may provide an automatic focusing (e.g., an auto focus) function. According to an embodiment, each pixel PX of the plurality of pixels PX may include sub-pixels including a plurality of photodiodes. Each of the sub-pixels included in the pixels PX according to embodiments may include a floating diffusion region, and a plurality of the floating diffusion regions may be connected to each other by metal lines. In a structure of the pixels PX according to embodiments, an increase in capacitance in the floating diffusion regions may be prevented or reduced by minimizing or reducing connection lengths of the metal lines connecting the floating diffusion regions respectively included in sub-pixels which are adjacent to each other, thereby ensuring a conversion gain. Examples of a structure of each pixel PX of the plurality of pixels PX and connection structures of the metal lines are described below with reference to FIG. 3 and the following figures.

In addition, each pixel PX of the plurality of pixels PX may include a pixel circuit for generating the pixel signals from charges generated by the photodiodes. In an embodiment, the pixel circuit may include a transfer transistor, a driving transistor, a selection transistor, a reset transistor, and the like. The pixel circuit may detect reset and pixel voltages from each pixel PX of the plurality of pixels PX and calculate the difference therebetween in order to obtain the pixel signal. The pixel voltage may include a voltage reflecting the charge generated by the photodiodes included in each pixel PX of the plurality of pixels PX.

When each pixel PX of the plurality of pixels PX includes two or more photodiodes, each pixel PX of the plurality of pixels PX may include the pixel circuit for processing the charge generated by each photodiode of the two or more photodiodes. For example, the pixel circuit may include two or more of at least one of a transfer transistor, a driving transistor, selection transistor, and a reset transistor depending on embodiments.

The row driver 120 may drive the pixel array 110 in row units. A plurality of row drivers 120 may drive the pixel array 110 by inputting a driving signal to the row lines. For example, the driving signal may include a transfer control signal TG which may be used to control the transfer transistor, a reset control signal RS which may be used to control the reset transistor, a selection control signal SEL which may be used to control the selection transistor of the pixel circuit, and the like. According to an embodiment, the row driver 120 may sequentially drive a plurality of row lines.

The readout circuit 130 may include a ramp signal generator 131, a sampling circuit 132, an analog-to-digital converter (ADC) 133, and a buffer 134. The sampling circuit 132 may include a plurality of samplers respectively connected to the pixels PX by a plurality of column lines and, in an embodiment, the sampler may include a correlated double sampler (CDS). The sampler may detect the reset and pixel voltages from the pixels PX connected to a selected row line driven by the row driver 120 among the plurality of row lines. The samplers may output the difference between the reset and pixel voltages as an analog signal.

The ADC 133 may compare the analog signal to a ramp voltage VRMP, convert a comparison result into a digital signal, and output the digital signal as image data LSB. The image data LSB may have a value which increases as the difference between the reset and pixel voltages increases. Accordingly, the image data LSB may have a value which increases as the amount of light received by the photodiodes increases.

The buffer 134 may temporarily store the image data LSB received from the ADC 133.

The row driver 120 and the readout circuit 130 may be controlled by the timing controller 140. The timing controller 140 may control operation timings of the row driver 120 and the readout circuit 130. The row driver 120 may control an operation of the pixel array 110 in row units in accordance with the control of the timing controller 140.

The signal processing circuit 150 may generate an image using the image data LSB transmitted from the buffer 134. The signal processing circuit 150 may process the image data LSB and output the processed image data as an image.

For example, the signal processing circuit 150 may interpolate the image data LSB corresponding to the pixel signals output from the pixels PX and may generate the interpolated image data. According to an embodiment, the image sensor 100 may perform bad pixel correction (BPC) using the pixel signals output from the photodiodes before the signal processing circuit 150 processes the image data LSB.

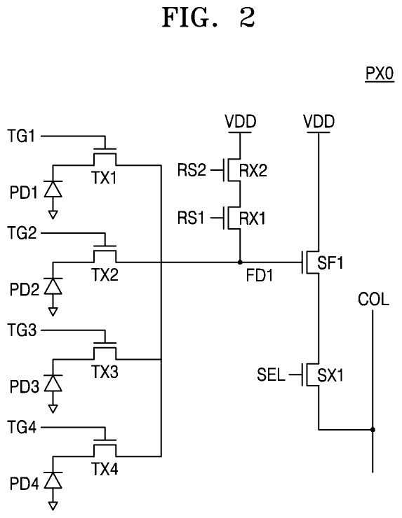

FIG. 2 is a circuit diagram illustrating a sub-pixel according to an embodiment. According to an embodiment, a sub-pixel PX0 of FIG. 2 may correspond to a sub-pixel included in the pixel PX of FIG. 1.

Referring to FIG. 2, the sub-pixel PX0 may include a first photodiode PD1, a second photodiode PD2, a third photodiode PD3, and a fourth photodiode PD4. In addition, the sub-pixel PX0 may include a first transistor TX1, a second transistor TX2, a third transistor TX3, and a fourth transistor TX4. The sub-pixel PX0 may also include a first floating diffusion node FD1, a first source follower transistor SF1, a first selection transistor SX1, and a first reset transistor, and a second reset transistor RX1 and RX2.

According to an embodiment, sub-pixel PX0 may accumulate charges corresponding to light incident on the image sensor 100 through first to fourth photodiodes PD1, PD2, PD3, and PD4. The amount of the charges accumulated in first to fourth photodiodes PD1, PD2, PD3, and PD4 may be referenced as light amount data.

According to an embodiment, the first to fourth transfer transistors TX1, TX2, TX3, and TX4 respectively connected to the first to fourth photodiodes PD1, PD2, PD3, and PD4 may have a dual vertical transfer gate structure. The dual vertical transfer gate structure may mean that two vertical transfer gates may correspond to one photodiode. The same transfer control signal may be applied to each of the two vertical transfer gates included in a dual vertical transfer gate.

The first reset transistor RX1 may be turned on and off (e.g., activated and deactivated) by a first reset control signal RS1, and the second reset transistor RX2 may be turned on and off (e.g., activated and deactivated) by a second reset control signal RS2. For example, when the first reset transistor RX1 and the second reset transistor RX2 are turned on, a voltage of the first floating diffusion node FD1 may be reset to a power supply voltage VDD. When the voltage of the first floating diffusion node FD1 is reset, the first selection transistor SX1 may be turned on by the selection control signal SEL and a reset voltage may be output to a column line COL.

According to an embodiment, the sub-pixel PX0 may determine whether to turn on the first reset transistor RX1 and the second reset transistor RX2 based on the illuminance. According to an embodiment, noise may be decreased by outputting an image in a state in which the first reset transistor RX1 and the second reset transistor RX2 are both turned off, and the first floating diffusion node FD1 may therefore have small capacitance at low illuminance. According to an embodiment, the first reset transistor RX1 may be turned on and the capacitance of the first floating diffusion node FD1 may therefore increase at high illuminance. Accordingly, the conversion gain may decrease or cover a high full-well capacity (FWC), therefore securing a dynamic range.

If the transfer control signals TG1, TG2, TG3, and TG4 respectively corresponding to the first to fourth transfer transistors TX1, TX2, TX3, and TX4 are applied to the first to fourth transfer transistors TX1, TX2, TX3, and TX4 after the reset voltage is output to the column line COL, electrons generated when the corresponding first to fourth photodiodes PD1, PD2, PD3, and PD4 are exposed to light may move to the first floating diffusion node FD1. The first source follower transistor SF1 may operate as a source-follower amplifier, for example by amplifying the voltage of the first floating diffusion node FD1, and when the first selection transistor SX1 is turned on by the selection control signal SEL, a pixel voltage corresponding to the electron generated by the corresponding photodiode may be output to the column line COL.

FIG. 3 is a circuit diagram illustrating a pixel according to an embodiment.

A pixel PX1 of FIG. 3 may include a first sub-pixel PX1a and a second sub-pixel PX1b. According to an embodiment, the first sub-pixel PX1a may be connected to the second sub-pixel PX1b. According to an embodiment, a circuit of the first sub-pixel PX1a may be the same as or similar to a circuit of the second sub-pixel PX1b. According to an embodiment, the circuit of the first sub-pixel PX1a and the circuit of the second sub-pixel PX1b may have a circuit structure corresponding to a circuit of the sub-pixel PX0 illustrated in FIG. 2. A circuit structure of the first sub-pixel PX1a and a circuit structure of the second sub-pixel PX1b may be the same as or similar to the circuit structures described above with reference to FIG. 2 and redundant or duplicative descriptions thereof may be omitted. According to an embodiment, the pixel PX1 illustrated in FIG. 3 may include a pixel having a 2×4 structure. According to embodiments, a pixel having a 2×4 structure may mean a pixel in which sub-pixels having four photodiodes in a 2×2 arrangement are arranged side by side in a Y-axis direction, such that the pixel includes a total of eight photodiodes. The pixel PX1 illustrated in FIG. 3 may include a set of sub-pixels, each of which includes four photodiodes.

Referring to FIG. 3, a first floating diffusion region FDA1 included in the first sub-pixel PX1a may be electrically connected to a second floating diffusion region FDA2 included in the second sub-pixel PX1b by a metal line. According to an embodiment, the first floating diffusion region FDA1 may include a region between a photoelectric conversion region corresponding to a photodiode adjacent to a first floating diffusion node FD1 and a first reset transistor RX1 adjacent to the first floating diffusion node FD1. According to an embodiment, the second floating diffusion region FDA2 may include a region between a photoelectric conversion region corresponding to a photodiode adjacent to a second floating diffusion node FD2 and the first reset transistor RX1 adjacent to the second floating diffusion node FD2. According to another embodiment, the first floating diffusion region FDA1 may include a region between a photoelectric conversion region corresponding to a photodiode adjacent to the second sub-pixel PX1b and the first reset transistor RX1 adjacent to the first floating diffusion node FD1. According to an embodiment, the second floating diffusion region FDA2 may include a region between a photoelectric conversion region corresponding to a photodiode adjacent to the first sub-pixel PX1a and the first reset transistor RX1 adjacent to the second floating diffusion node FD2.

According to embodiments, a floating diffusion region may refer to a sharing region between a photoelectric conversion region included in each sub-pixel and a reset transistor, and a floating diffusion node may refer to a node in which a set of transfer transistors contacts a reset transistor in a pixel circuit diagram.

According to an embodiment, the first floating diffusion region FDA1 may be adjacent to the second floating diffusion region FDA2 in a pixel layout. Therefore, capacitance of the floating diffusion regions may be decreased and conversion gain may be ensured by rendering the metal line connecting the first floating diffusion region FDA1 to the second floating diffusion region FDA2 short.

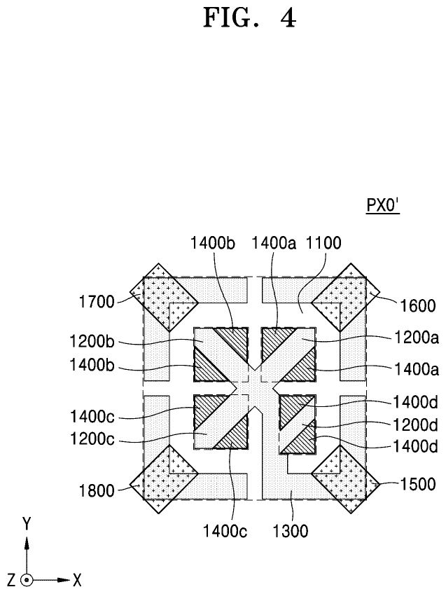

Examples of specific layouts of the first floating diffusion region FDA1 and the second floating diffusion region FDA2 are described below with reference to FIG. 4 and the following figures.

FIG. 4 is a plan view of a sub-pixel corresponding to the circuit diagram of FIG. 2.

FIG. 4 illustrates a layout plan view of a sub-pixel PX0′. The layout plan view may correspond to the sub-pixel PX0 of FIG. 2.

Referring to FIG. 4, the sub-pixel PX0′ may include a semiconductor substrate 1100, a first photoelectric conversion region 1200a, a second photoelectric conversion region 1200b, a third photoelectric conversion region 1200c, a further photoelectric conversion region 1200d, and a first floating diffusion region 1300 . . . . In addition, the sub-pixel PX0′ may include a first dual vertical transfer gate 1400a, a second dual vertical transfer gate 1400b, a third dual vertical transfer gate 1400c, a fourth dual vertical transfer gate 1400d, a first reset transistor 1500, a second reset transistor 1600, a selection transistor 1700, and a source-follower transistor 1800.

The semiconductor substrate 1100 may have a first surface and a second surface opposite thereto. In an embodiment, an image sensor including the sub-pixel PX0′ may include a backside illumination (BSI) image sensor.

According to an embodiment, vertical transfer gates (i.e., the first to fourth vertical transfer gates 1400a to 1400d) or the other transistors (e.g., the first reset transistor 1500, the second reset transistor 1600, the selection transistor 1700, and the source-follower transistor 1800) may be on the first surface (e.g., a front surface) of the semiconductor substrate 1100, and incident light may pass through the second surface (e.g., a back surface) of the semiconductor substrate 1100 and reach the first to fourth photoelectric conversion regions 1200a, 1200b, 1200c, and 1200d. In addition, in an embodiment, the semiconductor substrate 1100 may include a semiconductor layer formed through an epitaxial process. In an embodiment, the semiconductor substrate 1100 may be doped with first conductivity-type (e.g., p-type) impurities.

The first to fourth photoelectric conversion regions 1200a, 1200b, 1200c, and 1200d may be formed in the semiconductor substrate 1100 and may generate charges (e.g., photocharges) based on the incident light. For example, electron-hole pairs may be generated in response to the incident light and the first to fourth photoelectric conversion regions 1200a, 1200b, 1200c, and 1200d may collect these electrons or holes. According to an embodiment, the first to fourth photoelectric conversion regions 1200a, 1200b, 1200c, and 1200d may include at least one of a photodiode (PD), a pinned photodiode (PPD), a phototransistor, a photogate, and a combination thereof. According to an embodiment, each of the first to fourth photoelectric conversion regions 1200a, 1200b, 1200c, and 1200d may include regions respectively corresponding to the first to fourth photodiodes PD1, PD2, PD3, and PD4 of FIG. 2.

The first floating diffusion region 1300 may be spaced apart from the first to fourth photoelectric conversion regions 1200a, 1200b, 1200c, and 1200d formed in the semiconductor substrate 1100 in a Z-axis direction. The charges generated in the first to fourth photoelectric conversion regions 1200a, 1200b, 1200c, and 1200d may be transferred by the corresponding first to fourth vertical transfer gates 1400a, 1400b, 1400c, and 1400d, and stored in the first floating diffusion region 1300. In an embodiment, the first floating diffusion region 1300 may be doped with second conductivity-type (e.g., n-type) impurities. According to an embodiment, the first floating diffusion region 1300 may be located between the fourth photoelectric conversion region 1200d and a region in which the first reset transistor 1500 is located. According to an embodiment, the first floating diffusion region 1300 may be spaced apart from the fourth photoelectric conversion region 1200d in the Z-axis direction and may be provided in an L-shape that may be connected to the first reset transistor 1500 when viewed from above. According to an embodiment, the first floating diffusion region 1300 may be formed above the fourth photoelectric conversion region 1200d among the first to fourth photoelectric conversion regions 1200a, 1200b, 1200c, and 1200d.

Referring to FIG. 4, a direction in which the fourth vertical transfer gate 1400d, which may be located closest to the first floating diffusion region 1300 from among the first to fourth vertical transfer gates 1400a, 1400b, 1400c, and 1400d, is arranged may differ from directions in which the remaining vertical transfer gates (e.g., the first vertical transfer gate 1400a, the second vertical transfer gate 1400b, and the third vertical transfer gate 1400c) are arranged. According to an embodiment, the remaining vertical transfer gates (e.g., the first vertical transfer gate 1400a, the second vertical transfer gate 1400b, and the third vertical transfer gate 1400c) may be arranged in such a direction that the charges may be transferred toward the center of the sub-pixel PX0′. However, the fourth vertical transfer gate 1400d, which may be located closest to the first floating diffusion region 1300, may be arranged such that the charges may be transferred toward the first floating diffusion region 1300 rather than toward the center of the sub-pixel PX0′. A vertical transfer gate which is located closest to the first floating diffusion region 1300 may mean a vertical transfer gate corresponding to a photoelectric conversion region formed below the first floating diffusion region 1300. According to embodiments corresponding to FIG. 4, because the first floating diffusion region 1300 may be formed above the fourth photoelectric conversion region 1200d, the fourth vertical transfer gate 1400d may be the vertical transfer gate which is located closest to the first floating diffusion region 1300. According to an embodiment, in the fourth vertical transfer gate 1400d, which may be located closest to the first floating diffusion region 1300, a charge transfer path to the first floating diffusion region 1300 may be arranged, thereby ensuring a fast movement path of the charges.

The first to fourth vertical transfer gates 1400a, 1400b, 1400c, and 1400d may be formed in recesses extending from the first surface of the semiconductor substrate 1100 into the semiconductor substrate 1100 and on the first surface of the semiconductor substrate 1100. According to an embodiment, the first to fourth vertical transfer gates 1400a, 1400b, 1400c, and 1400d respectively corresponding to the first to fourth photoelectric conversion regions 1200a, 1200b, 1200c, and 1200d included in the sub-pixel PX0′ may be provided as a dual vertical transfer gate and may therefore be two in number. According to an embodiment, the two vertical transfer gates included in each of the first to fourth vertical transfer gates 1400a, 1400b, 1400c, and 1400d may be formed on both sides of the centers of the respectively corresponding first to fourth photoelectric conversion regions 1200a, 1200b, 1200c, and 1200d and may be spaced apart from each other in a parallel direction.

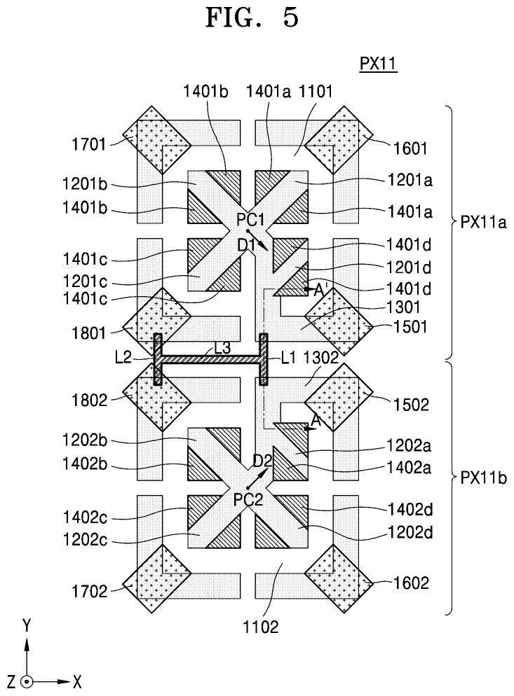

FIG. 5 is a plan view of a pixel corresponding to the circuit diagram of FIG. 3, according to an embodiment.

The plan view of a pixel PX11 illustrated in FIG. 5 may be a layout plan view of a first sub-pixel PX11a and a second sub-pixel PX11b located side by side in a second direction, that is, the Y-axis direction. According to an embodiment, the pixel PX11 illustrated in FIG. 5 may include a pixel having a 2×4 structure. According to an embodiment, a structure of the first sub-pixel PX11a may be the same as or similar to a structure of the sub-pixel PX0′ described above with reference to FIG. 4. A structure of the second sub-pixel PX11b may be symmetrical to the structure of the first sub-pixel PX11a with respect to the center point of the pixel PX11.

The first sub-pixel PX11a may include a first semiconductor substrate 1101, a a first photoelectric conversion region 1201a, a second photoelectric conversion region 1201b, a third photoelectric conversion region 1201c, a fourth photoelectric conversion region 1201d, and a first floating diffusion region 1301. In addition, the first sub-pixel PX11a may include a first dual vertical transfer gate 1401a, a second dual vertical transfer gate 1401b, a third dual vertical transfer gate 1401c, a fourth dual vertical transfer gate 1401d, a first reset transistor 1501, a second reset transistor 1601, a first selection transistor 1701, and a first source follower transistor 1801.

The second sub-pixel PX11b may include a second semiconductor substrate 1102, a fifth photoelectric conversion region 1202a, a sixth photoelectric conversion region 1202b, a seventh photoelectric conversion region 1202c, an eighth photoelectric conversion region 1202d, and a second floating diffusion region 1302. In addition, the second sub-pixel PX11b may include a fifth dual vertical transfer gate 1402a, a sixth dual vertical transfer gate 1402b, a seventh dual vertical transfer gate 1402c, an eighth dual vertical transfer gate 1402d, a third reset transistor 1502, a fourth reset transistor 1602, a second selection transistor 1702, and a second source follower transistor 1802.

Components included in the first sub-pixel PX11a and the second sub-pixel PX11b described with reference to FIG. 5 may correspond to components of the sub-pixel PX0′ described with reference to FIG. 4, and redundant or duplicative descriptions thereof may be omitted.

Referring to FIG. 5, the first floating diffusion region 1301 may be connected to the second floating diffusion region 1302 by a first metal line L1. According to an embodiment, the first floating diffusion region 1301 may face the second floating diffusion region 1302. The first floating diffusion region 1301 may be provided with a structure symmetrical to the second floating diffusion region 1302 with respect to an axis between the first sub-pixel PX11a and the second sub-pixel PX11b. According to an embodiment, the first floating diffusion region 1301 and the second floating diffusion region 1302 may be provided in an L-shape when viewed from above. Referring to FIG. 5, the first floating diffusion region 1301 may be in an L-shape and the second floating diffusion region 1302 may be provided in a shape that is symmetrical to the L-shape with respect to the X-axis.

The first floating diffusion region 1301 may be formed in a direction biased to any one side with respect to a center point PC1 of the first sub-pixel PX11a. According to an embodiment, the first floating diffusion region 1301 may be formed in a direction biased to a first diagonal direction D1 with respect to the center point PC1 of the first sub-pixel PX11a.

The second floating diffusion region 1302 may be formed in a direction biased to any one side with respect to a center point PC2 of the second sub-pixel PX11b. According to an embodiment, the second floating diffusion region 1302 may be formed in a direction biased to a second diagonal direction D2 with respect to the center point PC2 of the second sub-pixel PX11b.

According to an embodiment, the first diagonal direction D1 may have an angle difference of 90 degrees from the second diagonal direction D2. For example, the first diagonal direction D1 may be perpendicular to the second diagonal direction D2.

According to an embodiment, the first floating diffusion region 1301 may be biased in a direction adjacent to the second sub-pixel PX11b in the first sub-pixel PX11a. According to an embodiment, the second floating diffusion region 1302 may be biased in a direction adjacent to the first sub-pixel PX11a in the second sub-pixel PX11b.

According embodiments, the first floating diffusion region 1301 and the second floating diffusion region 1302 may be formed in a direction biased to any one side in comparison with the center point of each sub-pixel. Accordingly, a length of the first metal line L1 for connecting the first floating diffusion region 1301 to the second floating diffusion region 1302 and sharing a floating diffusion node may be minimized and conversion gain may thus be ensured. A length of the first metal line L1 in the Y-axis direction may be shorter than a length of a line connecting the center point PC1 of the first sub-pixel PX11a to the center point PC2 of the second sub-pixel PX11b in the Y-axis direction.

In addition, the first floating diffusion region 1301 may share source/drain regions of the first reset transistor 1501. The second floating diffusion region 1302 may share source/drain regions of the third reset transistor 1502. Accordingly, an area size of a junction may decrease.

Referring to FIG. 5, the first reset transistor 1501 included in the first sub-pixel PX11a may face the third reset transistor 1502 included in the second sub-pixel PX11b. According to an embodiment, the first floating diffusion region 1301 may be located adjacent to the first reset transistor 1501 of the first sub-pixel PX11a and the second floating diffusion region 1302 may be located adjacent to the third reset transistor 1502 of the second sub-pixel PX11b.

Referring to FIG. 5, the first source follower transistor 1801 of the first sub-pixel PX11a may face the second source follower transistor 1802 of the second sub-pixel PX11b.

Because reset transistors and source follower transistors may face each other, a length of each of metal lines connecting therebetween may be the same or similar. According to an embodiment, the length of the first metal line L1 for connecting the reset transistors facing each other may be the same as or similar to a length of a second metal line L2 for connecting the source follower transistors facing each other. The length of the first metal line L1 and the length of the second metal line L2 may be shorter than the length of the line connecting the center point of the first sub-pixel PX11a to the center point of the second sub-pixel PX11b.

According to the disclosure, positions of the floating diffusion regions may be changed in the pixel structure having the 2×4 structure and sharing the floating diffusion regions.

According to a comparative example, positions of floating diffusion regions may be fixed to a center point of each sub-pixel. Therefore, an issue of metal wiring being fixed may occur when the floating diffusion regions are connected and shared in the 2×4 structure. Capacitance of the floating diffusion regions may be reduced in order to maximize high conversion gain.

According to embodiments, the metal line wiring may be minimized by changing the positions of the floating diffusion regions and the area of the junction of the floating diffusion regions may be reduced, thereby reducing the capacitance of the floating diffusion regions. According to embodiments of the disclosure, positions of a floating diffusion region corresponding to a source portion of a gate of a reset transistor and a floating diffusion region corresponding to a transfer transistor may be shared and used as the same position, thereby reducing the area of the junction of the floating diffusion regions. Accordingly, capacitance of the floating diffusion node may be minimized so that high conversion gain may be maximized and a noise component in an electron unit may be improved.

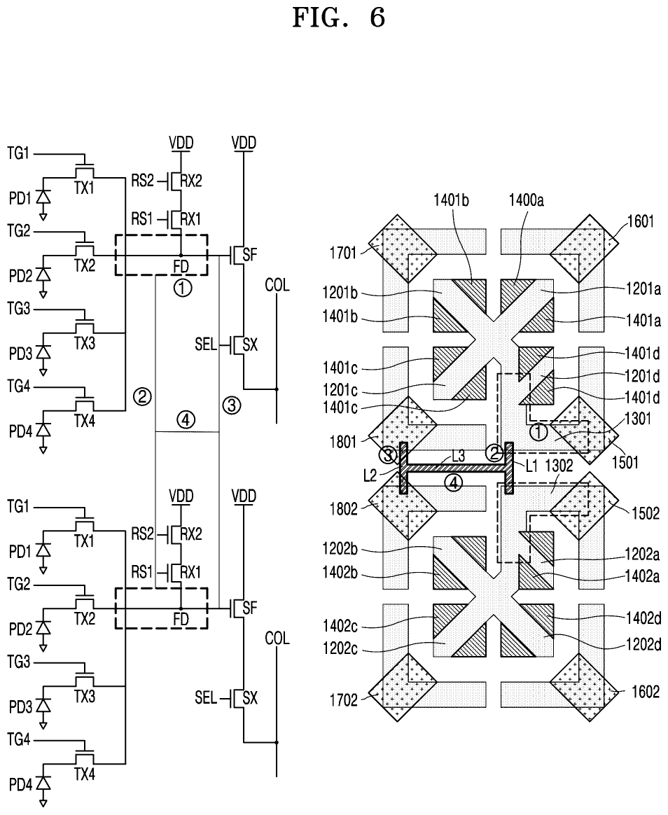

FIG. 6 is a diagram for explaining a correspondence between the circuit diagram of the pixel of FIG. 3 and the plan view of the pixel of FIG. 5, according to an embodiment.

Referring to FIG. 6, component (1) may correspond to the first floating diffusion region 1301 and the second floating diffusion region 1302, component (2) may correspond to the first metal line L1 connecting the first floating diffusion region 1301 to the second floating diffusion region 1302, component 3 may correspond to the second metal line L2 connecting the first source follower transistor 1801 to the second source follower transistor 1802, and component (4) may include a third metal line L3 electrically connecting the first metal line L1 to the second metal line L2.

As shown in FIG. 6, the first floating diffusion region 1301 and the second floating diffusion region 1302 corresponding to component (1) may represent regions connecting floating diffusion nodes that are connected to photodiodes included in each of sub-pixels to a floating diffusion node that is connected to a reset transistor.

According embodiments, floating diffusion regions of each of the sub-pixels adjacent to each other may be located relatively close to each other. According to embodiments, the floating diffusion region included in each of the sub-pixels may include a region sharing a floating diffusion node by a transfer transistor and a floating diffusion node by a reset transistor.

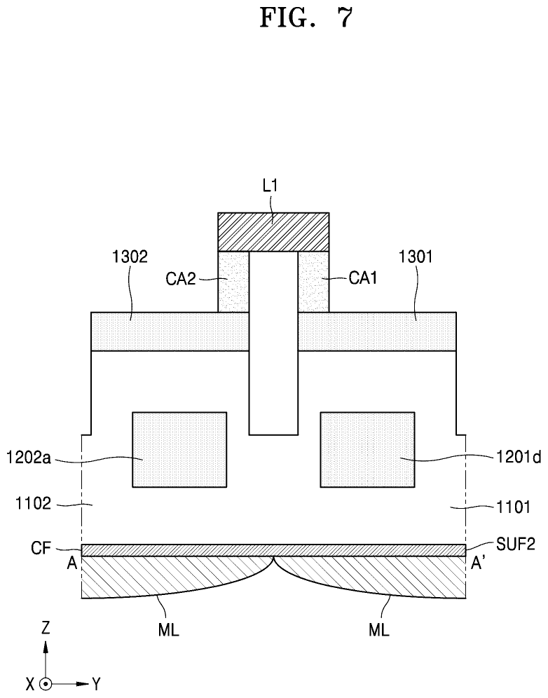

FIG. 7 is a cross-sectional view of the pixel of FIG. 5, according to an embodiment.

In particular, FIG. 7 illustrates an example of a cross-sectional view of the pixel of FIG. 5 taken along line A-A′ according to an embodiment. As shown in FIG. 7, the first floating diffusion region 1301 may be located adjacent to the second floating diffusion region 1302. In addition, FIG. 7 illustrates a configuration in which the first metal line L1 is connected through a first contact CA1 extending in the Z-axis from the first floating diffusion region 1301 and a second contact CA2 extending in the Z-axis direction from the second floating diffusion region 1302.

Referring to FIG. 7, the first floating diffusion region 1301 may be formed above the fourth photoelectric conversion region 1201d and the second floating diffusion region 1302 may be formed above the fifth photoelectric conversion region 1202a. The length of the first metal line L1 may be minimized because the first floating diffusion region 1301 and the second floating diffusion region 1302 may be formed above the photoelectric conversion regions biased to any one side.

Referring to the cross-sectional view of FIG. 7, a color filter CF may be formed on a second surface SUF2 of the first and second semiconductor substrates 1101 and 1102 and correspond to the fifth and fourth photoelectric conversion regions 1202a and 1201d. The color filter CF may be included in a color filter array arranged in a matrix form. In an embodiment, the color filter array may have a Bayer pattern including a red filter, a green filter, and a blue filter. In another embodiment, the color filter array may include a yellow filter, a magenta filter, and a cyan filter. In addition, the color filter array may further include a white filter. In addition, a reflection-preventing layer, at least one insulating layer, and the like may be formed between the second surface SUF2 of the first and second semiconductor substrates 1101 and 1102 and the color filter CF, depending on embodiments.

Microlenses ML may be formed to correspond to the color filter CF and the fifth and fourth photoelectric conversion regions 1202a and 1201d. The microlenses ML may adjust a path of light incident to the microlenses ML such that the incident light concentrates on the fifth and fourth photoelectric conversion regions 1202a and 1201d. In addition, the microlenses ML may be included in a microlens array arranged in a matrix form.

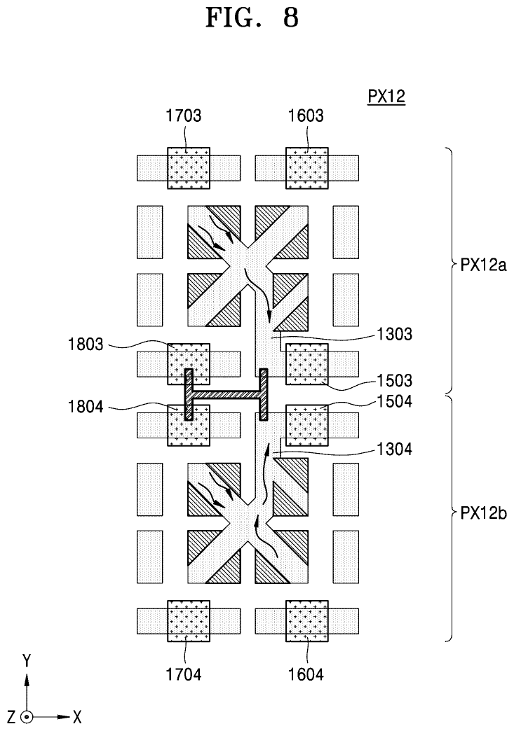

FIG. 8 is a plan view of a pixel according to an embodiment.

A pixel PX12 of FIG. 8 may include a first sub-pixel PX12a and a second sub-pixel PX12b. Redundant or duplicative descriptions of components of the pixel of FIG. 5 described above may be omitted in the description of the plan view of the pixel of FIG. 8.

As shown in FIG. 8, transistors 1503, 1603, 1703, and 1803 included in the first sub-pixel PX12a and transistors 1504, 1604, 1704, and 1804 included in the second sub-pixel PX12b of FIG. 8 may be located at positions other than edge regions of each of the sub-pixels. Accordingly, a shape of a first floating diffusion region 1303 and a second floating diffusion region 1304 may differ from FIG. 5. That is, arrangement positions of the transistors included in each of the sub-pixels may be different compared to FIG. 5.

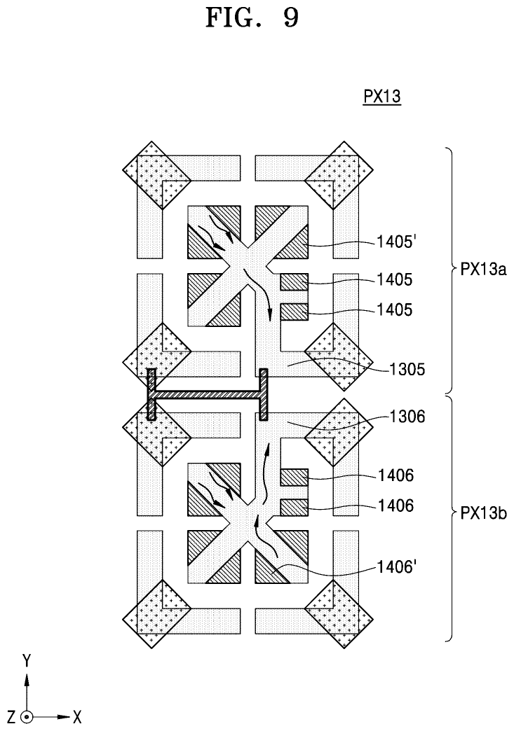

FIG. 9 is a plan view of a pixel according to an embodiment.

A pixel PX13 of FIG. 9 may include a first sub-pixel PX13a and a second sub-pixel PX13b. Redundant or duplicative descriptions of components of the pixel of FIG. 5 described above may be omitted in the description of the plan view of the pixel of FIG. 9.

As shown in FIG. 9, a structure of a vertical transfer gate 1405 corresponding to a photoelectric conversion region adjacent to a first floating diffusion region 1305 included in the first sub-pixel PX13a may differ from that of a vertical transfer gate 1405′ corresponding to a photoelectric conversion region not adjacent to the first floating diffusion region 1305 included in the first sub-pixel PX13a.

In addition, a structure of a vertical transfer gate 1406 corresponding to a photoelectric conversion region adjacent to a second floating diffusion region 1306 included in the second sub-pixel PX13b may differ from that of a vertical transfer gate 1406′ corresponding to a photoelectric conversion region not adjacent to the second floating diffusion region 1306 included in the second sub-pixel PX13b.

According to an embodiment, the structure of the vertical transfer gate 1405 corresponding to the photoelectric conversion region adjacent to the first floating diffusion region 1305 included in the first sub-pixel PX13a and the structure of the vertical transfer gate 1406 corresponding to the photoelectric conversion region adjacent to the second floating diffusion region 1306 included in the second sub-pixel PX13b may be provided as a dual vertical transfer gate structure with rectangular shapes spaced apart from each other in the Y-axis direction.

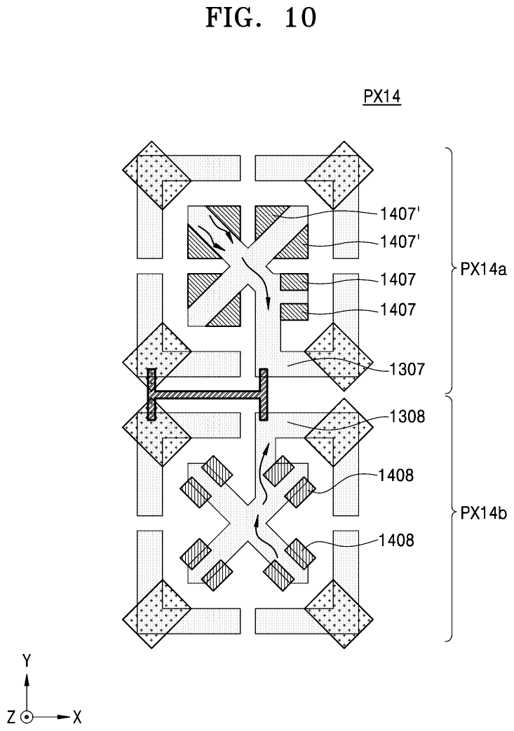

FIG. 10 is a plan view of a pixel according to an embodiment.

A pixel PX14 of FIG. 10 may include a first sub-pixel PX14a and a second sub-pixel PX14b. Redundant or duplicative descriptions of components of the pixel of FIG. 5 described above may be omitted in the description of the plan view of the pixel of FIG. 10.

As shown in FIG. 10, a structure of the first sub-pixel PX14a may be the same as or similar to a structure of the first sub-pixel PX13a illustrated in FIG. 9. In a structure of the second sub-pixel PX14b, arrangement directions of vertical transfer gates 1408 corresponding to a plurality of photoelectric conversion regions may differ from that of vertical transfer gates 1407 included in the first sub-pixel PX14a. The dual vertical transfer gates 1408 included in the second sub-pixel PX14b may be provided with a structure symmetrical to each other.

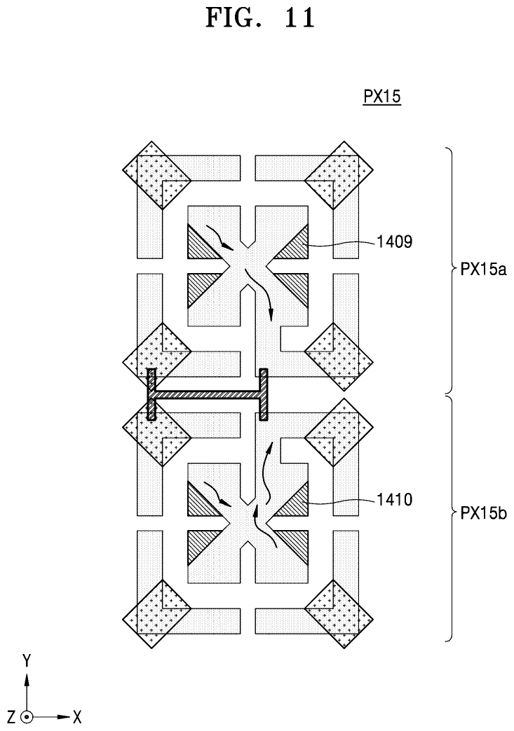

FIG. 11 is a plan view of a pixel according to an embodiment.

A pixel PX15 of FIG. 11 may include a first sub-pixel PX15a and a second sub-pixel PX15b. Redundant or duplicative descriptions of components of the pixel of FIG. 5 described above may be omitted in the description of the plan view of the pixel of FIG. 11.

As shown in FIG. 11, vertical transfer gates 1409 and 1410 included in the first sub-pixel PX15a and the second sub-pixel PX15b may be provided as a single vertical transfer gate. Referring to FIG. 11, the vertical transfer gates corresponding to photoelectric conversion regions included in the first sub-pixel PX15a and the second sub-pixel PX15b may include single vertical transfer gates rather than dual vertical transfer gates.

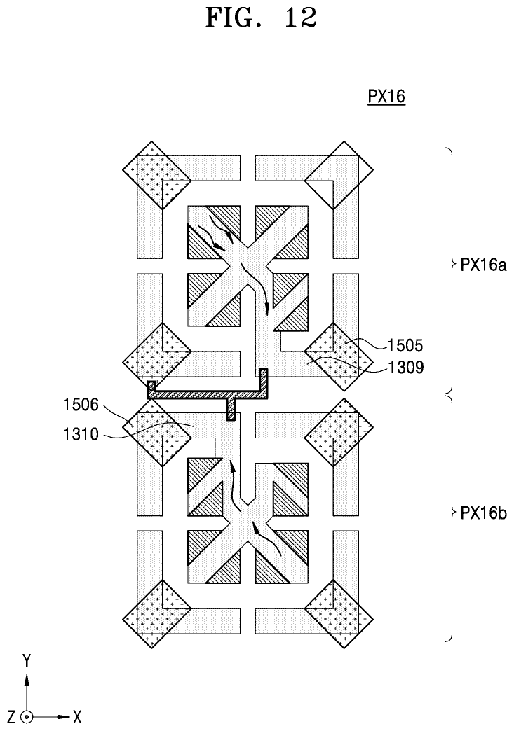

FIG. 12 is a plan view of a pixel according to an embodiment.

A pixel PX16 of FIG. 12 may include a first sub-pixel PX16a and a second sub-pixel PX16b. Redundant or duplicative descriptions of components of the pixel of FIG. 5 described above may be omitted in the description of the plan view of the pixel of FIG. 12.

Referring to FIG. 12, a first floating diffusion region 1309 included in the first sub-pixel PX16a may be adjacent to a second floating diffusion region 1310 included in the second sub-pixel PX16b in a diagonal direction. Referring to FIG. 12, an arrangement position of a first reset transistor 1505 included in the first sub-pixel PX16a may be adjacent to an arrangement position of a third reset transistor 1506 included in the second sub-pixel PX16b in a diagonal direction. According to an embodiment, the arrangement position of the first reset transistor 1505 included in the first sub-pixel PX16a may not face the arrangement position of the third reset transistor 1506 included in the second sub-pixel PX16b.

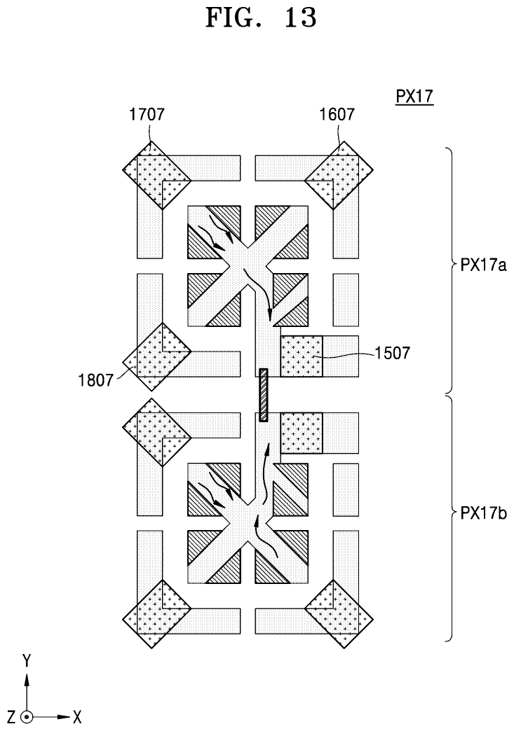

FIG. 13 is a plan view of a pixel according to an embodiment.

A pixel PX17 of FIG. 13 may include a first sub-pixel PX17a and a second sub-pixel PX17b. Redundant or duplicative descriptions of the pixel of FIG. 5 described above may be omitted in the description of the plan view of the pixel of FIG. 13.

Referring to FIG. 13, an arrangement structure of a first reset transistor 1507 included in the first sub-pixel PX17a may differ from that of the other transistors 1607, 1707, and 1807 included in the first sub-pixel PX17a. According to an embodiment, arrangement structures and gate structures of transistors included in one sub-pixel may not all be the same and may be located in different positions as in the example of FIG. 13.

Arrows shown in FIGS. 8 to 13 may illustrate a path of charges moving from a plurality of photoelectric conversion regions to floating diffusion regions according to an embodiment. When dual vertical transfer gates are arranged according to embodiments, a charge movement to the floating diffusion regions may be facilitated.

Embodiments described with reference to the plan views of the pixels of FIGS. 8 to 13 are only illustrative, and are not intended to be limiting. With regard to a pixel according to embodiments, arrangement positions or structures of transistors or vertical transfer gates included in sub-pixels may be modified and applied, a shape or number of the vertical transfer gates may be adjusted, and a size of junction of the floating diffusion regions may be changed.

An image sensor according to embodiments may change positions of the floating diffusion regions connecting the sub-pixels in a 2×4 pixel structure. The image sensor according to embodiments may make it possible to change the positions of the floating diffusion regions connecting the sub-pixels to positions located in a direction corresponding to any one of photoelectric conversion regions included in the sub-pixels in the 2×4 pixel structure. Embodiments may allow the positions of the floating diffusion regions to be changed from centers of sub-pixels according to a comparative example to any one side of the photoelectric conversion regions, through which the positions of the floating diffusion regions included in the sub-pixels may be located close to each other. Accordingly, metal wiring may be minimized and floating diffusion regions of a transfer transistor and a reset transistor may be used as the same position, thereby maximizing conversion gain.

While the inventive concept has been particularly shown and described with reference to embodiments thereof, it will be understood that various changes in form and details may be made therein without departing from the spirit and scope of the following claims.

What is claimed is:

1. A pixel comprising:
a first sub-pixel comprising a plurality of first photodiodes and a first reset transistor; and
a second sub-pixel comprising a plurality of second photodiodes and a second reset transistor,
wherein the first sub-pixel shares a floating diffusion node with the second sub-pixel, and
wherein a length in a first direction of a metal line for sharing the floating diffusion node is shorter than a length in the first direction of a line connecting a center point of the first sub-pixel to a center point of the second sub-pixel.

2. The pixel of claim 1, wherein a first floating diffusion region included in the first sub-pixel is electrically connected to a second floating diffusion region included in the second sub-pixel by the metal line.

3. The pixel of claim 2, wherein the first floating diffusion region is between a photoelectric conversion region corresponding to a first photodiode adjacent to the second sub-pixel from among the plurality of first photodiodes and the first reset transistor, and
wherein the second floating diffusion region is between a photoelectric conversion region corresponding to a second photodiode adjacent to the first sub-pixel from among the plurality of second photodiodes and the second reset transistor.

4. The pixel of claim 3, wherein a structure of the first floating diffusion region is symmetrical to a structure of the second floating diffusion region.

5. The pixel of claim 3, wherein the first floating diffusion region and the second floating diffusion region are in an L-shape in a view from above the pixel.

6. The pixel of claim 2, wherein the first floating diffusion region is in a direction adjacent to the second sub-pixel within the first sub-pixel, and
wherein the second floating diffusion region is in a direction adjacent to the first sub-pixel within the second sub-pixel.

7. The pixel of claim 1, wherein the first sub-pixel comprises four first photodiodes, and
wherein the second sub-pixel comprises four second photodiodes.

8. A pixel comprising:
a first sub-pixel; and
a second sub-pixel,
wherein the first sub-pixel comprises:
a first plurality of photoelectric conversion regions comprising a first photoelectric conversion region, a second photoelectric conversion region, a third photoelectric conversion region, and a fourth photoelectric conversion region; and
a first floating diffusion region,
wherein the first plurality of photoelectric conversion regions and the first floating diffusion region are spaced apart in a direction perpendicular to the first plurality of photoelectric conversion regions,
wherein the second sub-pixel comprises:
a second plurality of photoelectric conversion regions comprising a fifth photoelectric conversion region, a sixth photoelectric conversion region, a seventh photoelectric conversion region, and an eighth photoelectric conversion region; and
a second floating diffusion region,
wherein the second plurality of photoelectric conversion regions and the second floating diffusion region are spaced apart in a direction perpendicular to the second plurality of photoelectric conversion regions,
wherein the first floating diffusion region is connected to the second floating diffusion region by a first metal line,
wherein the first floating diffusion region is above the first plurality of photoelectric conversion regions, and
wherein the second floating diffusion region is above the second plurality of photoelectric conversion regions.

9. The pixel of claim 8, wherein the first floating diffusion region and the second floating diffusion region are in an L-shape in a view from above the pixel.

10. The pixel of claim 8, wherein the first floating diffusion region is adjacent to a first reset transistor included in the first sub-pixel, and
the second floating diffusion region is adjacent to a second reset transistor included in the second sub-pixel.

11. The pixel of claim 10, wherein a location of the first reset transistor is symmetrical to a location of the second reset transistor.

12. The pixel of claim 8, wherein a location of a first source follower transistor included in the first sub-pixel is symmetrical to a location of a second source follower transistor included in the second sub-pixel.

13. The pixel of claim 12, wherein the first source follower transistor is connected to the second source follower transistor by a second metal line.

14. The pixel of claim 13, wherein a length of the first metal line is equal to a length of the second metal line.

15. The pixel of claim 14, wherein the length of the first metal line and the length of the second metal line are shorter than a length of a line connecting a center point of the first sub-pixel to a center point of the second sub-pixel in a first direction.

16. A pixel having a 2×4 structure, the pixel comprising:
a first sub-pixel; and
a second sub-pixel,
wherein a structure of the first sub-pixel is symmetrical to a structure of the second sub-pixel with respect to a center point of the pixel, and
wherein a length of a first metal line connecting a first floating diffusion region of the first sub-pixel to a second floating diffusion region included in the second sub-pixel is shorter than a length of a line connecting a center point of the first sub-pixel to a center point of the second sub-pixel.

17. The pixel of claim 16, wherein the first floating diffusion region is in a direction biased to a first diagonal direction with respect to the center point of the first sub-pixel,
wherein the second floating diffusion region is in a direction biased to a second diagonal direction with respect to the center point of the second sub-pixel, and
wherein the first diagonal direction is perpendicular to the second diagonal direction.

18. The pixel of claim 16, wherein the first floating diffusion region and the second floating diffusion region are in an L-shape in a view from above the pixel.

19. The pixel of claim 16, wherein the first floating diffusion region is adjacent to a reset transistor included in the first sub-pixel, and
wherein the second floating diffusion region is adjacent to a reset transistor included in the second sub-pixel.

20. The pixel of claim 16, wherein a location of a source follower transistor included in the first sub-pixel is symmetrical to a location of a source follower transistor included in the second sub-pixel.
